(19) United States
(12) Patent Application Publication
(10) Pub. No.: US 2024/0429198 A1
(43) Pub. Date: Dec. 26, 2024

(54) SEMICONDUCTOR PACKAGE AND METHOD OF MANUFACTURING THE SAME

(71) Applicant: Samsung Electronics Co., Ltd., Suwon-si (KR)

(72) Inventors: Jing Cheng LIN, Suwon-si (KR); Youngkun JEE, Suwon-si (KR)

(73) Assignee: Samsung Electronics Co., Ltd., Suwon-si (KR)

(21) Appl. No.: 18/753,612

(22) Filed: Jun. 25, 2024

(30) Foreign Application Priority Data
Jun. 26, 2023 (KR) 10-2023-0082130

(51) Int. Cl. H01L 23/00; H01L 23/31; H01L 23/498; H01L 23/544; H01L 25/00; H01L 25/065; H01L 25/16; H10B 80/00

(52) U.S. Cl. CPC H01L 24/96; H01L 23/3107; H01L 23/544; H01L 24/24; H01L 25/50; H01L 23/49816; H01L 25/0655; H01L 25/16; H01L 2223/54426; H01L 2224/244; H01L 2224/24991; H01L 2224/95001; H01L 2224/95146; H10B 80/00

(57) ABSTRACT

A method of manufacturing a semiconductor package according to embodiments of the present disclosure has an effect of reducing the size of the semiconductor package by minimizing a distance between semiconductor chips by self-aligning the semiconductor chips on pads having fine gaps due to the surface tension of solder bumps.

### CROSS-REFERENCE TO RELATED APPLICATION

This application is based on and claims priority under 35 U.S.C. § 119 to Korean Patent Application No. 10-2023-0082130, filed on Jun. 26, 2023, in the Korean Intellectual Property Office, the disclosure of which is incorporated by reference herein in its entirety.

### BACKGROUND

The present disclosure relates to a semiconductor package and a method of manufacturing the same, and more particularly, to a method of manufacturing a semiconductor package including a silicon die.

Recently, due to significant progress in the electronics industry and the demand of users, electronic devices are becoming more compact and multi-functional and have greater capacity, thus requiring a highly integrated semiconductor chip. Therefore, a semiconductor package is being designed that includes a highly integrated semiconductor chip with an increased number of connection terminals for input/output (I/O) and simultaneously has ensured connection reliability. For example, a semiconductor package is being developed that includes a silicon die between connection terminals.

### SUMMARY

Embodiments of the present disclosure provide a method of manufacturing a semiconductor package, by which the size of the semiconductor package may be reduced by minimizing a distance between semiconductor chips by self-aligning the semiconductor chips on pads having fine gaps due to the surface tension of solder bumps.

Embodiments of the present disclosure are not limited to solving the problems mentioned above, and other problems, not mentioned above, that are solved by embodiments of the present disclosure will be clearly understood by those skilled in the art from the following description.

According to an aspect of an example embodiment, a method of manufacturing a semiconductor package includes: forming a plurality of sacrificial pads on a first carrier substrate; forming a plurality of sacrificial solder bumps on the plurality of sacrificial pads; arranging, on the plurality of sacrificial solder bumps, a first semiconductor chip, a second semiconductor chip, and a bridge die that are spaced apart from each other in a horizontal direction, each of the first semiconductor chip, the second semiconductor chip, and the bridge die including a lower surface on which a plurality of metal pillars and a protective insulating layer surrounding side surfaces of the plurality of metal pillars are provided; bonding the plurality of sacrificial solder bumps to the plurality of metal pillars that are on the lower surface of the first semiconductor chip, the second semiconductor chip, and the bridge die, such that the plurality of sacrificial solder bumps is between the first carrier substrate and each of the first semiconductor chip, the second semiconductor chip, and the bridge die; forming a molding layer that surrounds the plurality of sacrificial pads, the plurality of sacrificial solder bumps, the protective insulating layer, the first semiconductor chip, the second semiconductor chip, and the bridge die; attaching a second carrier substrate onto the first semiconductor chip and the second semiconductor chip, and removing the first carrier substrate; exposing surfaces of the plurality of metal pillars and a surface of the protective insulating layer by grinding and removing all of the plurality of sacrificial pads and the plurality of sacrificial solder bumps; forming a redistribution layer on the plurality of metal pillars and the protective insulating layer; forming an external connection terminal on the redistribution layer; and removing the second carrier substrate.

According to an aspect of an example embodiment, a method of manufacturing a semiconductor package includes: forming a plurality of sacrificial pads on a first carrier substrate; forming a plurality of sacrificial solder bumps on the plurality of sacrificial pads; arranging, on the plurality of sacrificial solder bumps, a first semiconductor chip, a second semiconductor chip, a first passive device, and a second passive device, wherein each the first semiconductor chip, the second semiconductor chip, the first passive device, and the second passive device comprises a lower surface on which a plurality of metal pillars are provided; bonding the plurality of sacrificial solder bumps to the plurality of metal pillars, such that the plurality of sacrificial sold bumps is between the first carrier substrate and each of the first semiconductor chip, the second semiconductor chip, the first passive device, and the second passive device; forming a molding layer that surrounds the plurality of sacrificial pads, the plurality of sacrificial solder bumps, the plurality of metal pillars, the first semiconductor chip, the second semiconductor chip, the first passive device, and the second passive device; attaching a second carrier substrate onto the first semiconductor chip and the second semiconductor chip, and removing the first carrier substrate; exposing surfaces of the plurality of metal pillars by grinding and removing all of the plurality of sacrificial pads and the plurality of sacrificial solder bumps; forming a redistribution layer on the plurality of metal pillars and the molding layer; forming an external connection terminal on the redistribution layer; and removing the second carrier substrate.

According to an aspect of an example embodiment, a method of manufacturing a semiconductor package includes: forming a plurality of sacrificial pads on a first carrier substrate; forming a plurality of sacrificial solder bumps on the plurality of sacrificial pads; arranging, on the plurality of sacrificial solder bumps, a first semiconductor chip, a second semiconductor chip, and a bridge die, each of the first semiconductor chip, the second semiconductor chip, and the bridge die comprising a lower surface on which a plurality of metal pillars and a protective insulating layer surrounding side surfaces of the plurality of metal pillars are provided; bonding the plurality of sacrificial solder bumps to the plurality of metal pillars, such that the plurality of sacrificial solder bumps is between the first carrier substrate and each of the first semiconductor chip, the second semiconductor chip, and the bridge die; forming a molding layer that surrounds the plurality of sacrificial pads, the plurality of sacrificial solder bumps, the protective insulating layer, the first semiconductor chip, the second semiconductor chip, and the bridge die; attaching a second carrier substrate onto the first semiconductor chip and the second semiconductor chip, and removing the first carrier substrate; exposing surfaces of the plurality of metal pillars and a surface of the protective insulating layer by grinding and removing all of the plurality of sacrificial pads and the plurality of sacrificial solder bumps; forming a first redistribution layer on the plurality of metal pillars and the protective insulating layer; attaching a third carrier substrate onto the first redistribution layer and removing the second carrier substrate; forming a plurality of connection posts that are arranged around the first semiconductor chip and the second semiconductor chip, and are electrically connected with the first redistribution layer through the molding layer; forming a second redistribution layer on the molding layer, the plurality of connection posts, the first semiconductor chip, and the second semiconductor chip; arranging a third semiconductor chip on the second redistribution layer; and removing the third carrier substrate.

### BRIEF DESCRIPTION OF THE DRAWINGS

The above and/or other aspects will be more clearly understood from the following detailed description taken in conjunction with the accompanying drawings in which:

FIG. 1 is a plan view of main components of a semiconductor package according to an embodiment;

FIG. 2 is a cross-sectional view of the semiconductor package of FIG. 1 taken along line CX1-CX1′ of FIG. 1;

FIG. 3 is a view illustrating an embodiment of the present disclosure;

FIG. 4 is a view illustrating an embodiment of the present disclosure;

FIG. 5 is a plan view of main components of a semiconductor package according to embodiment;

FIG. 6 is a cross-sectional view of the semiconductor package of FIG. 5 taken along line CX2-CX2′ of FIG. 5;

FIG. 7 is a plan view illustrating an embodiment of the present disclosure;

FIG. 8 is a flowchart illustrating a method of manufacturing a semiconductor package, according to an embodiment;

FIGS. 9 to 17 are views illustrating, in a process order, a method of manufacturing a semiconductor package, according to an embodiment;

FIG. 18 is a flowchart illustrating a method of manufacturing a semiconductor package, according to an embodiment; and

FIGS. 19 to 25 are views illustrating, in a process order, a method of manufacturing a semiconductor package, according to embodiment.

### DETAILED DESCRIPTION

Hereinafter, non-limiting example embodiments of the present disclosure will be described in detail with reference to the accompanying drawings.

Throughout the specification, an upper surface/above/on and a lower surface/under/below may be applied differently depending on the direction shown in each drawing. For example, an upper surface/above/on in one drawing (a drawing with a vertical arrow pointing upward) may be referred to as a lower surface/under/below in another drawing (a drawing with a vertical arrow pointing downward).

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

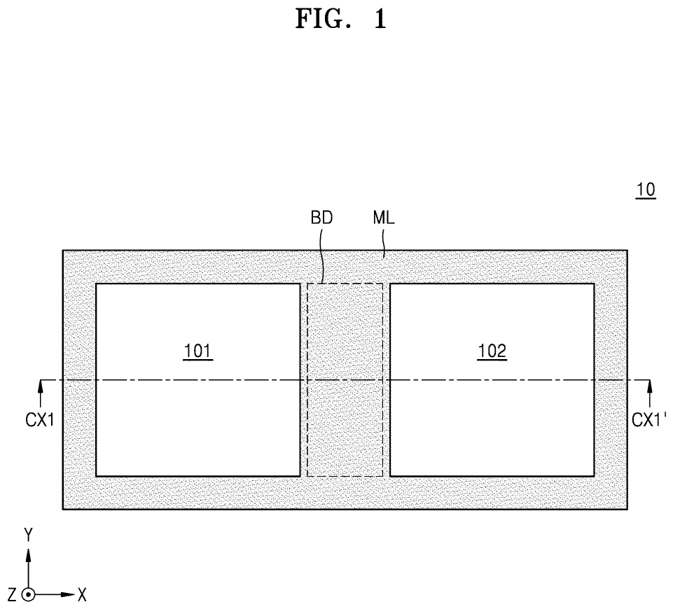

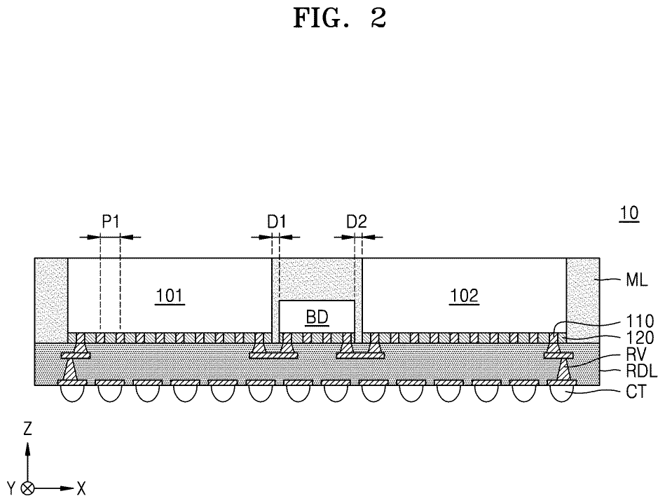

FIG. 1 is a plan view of main components of a semiconductor package according to an embodiment, and FIG. 2 is a cross-sectional view of the semiconductor package of FIG. 1 taken along line CX1-CX1′ of FIG. 1.

Referring to FIGS. 1 and 2, a semiconductor package 10 is shown that includes a first semiconductor chip 101 and a second semiconductor chip 102 arranged apart from each other in a first horizontal direction X and a bridge die BD arranged therebetween.

Each of the first semiconductor chip 101 and the second semiconductor chip 102 may be a memory chip, and for example, may include a volatile memory chip and/or a non-volatile memory chip. In some embodiments, the first semiconductor chip 101 and the second semiconductor chip 102 may be configured as a set of memory chips capable of merging data with each other.

Each of the first semiconductor chip 101 and the second semiconductor chip 102 may include a semiconductor substrate having upper and lower surfaces facing away from other, and a plurality of metal pillars 110 formed on a lower surface of the semiconductor substrate. A protective insulating layer 120 may surround side surfaces of the plurality of metal pillars 110. According to embodiments, the length of each of the plurality of metal pillars 110 in a vertical direction Z may be substantially the same as the length of the protective insulating layer 120 in the vertical direction Z.

Some of the plurality of metal pillars 110 disposed below the first semiconductor chip 101 and the second semiconductor chip 102 may be connected to an external connection terminal CT via a redistribution layer RDL. In addition, the others of the plurality of metal pillars 110 disposed below the first semiconductor chip 101 and the second semiconductor chip 102 may be connected to the bridge die BD via the redistribution layer RDL.

In a system in package in which a plurality of individual semiconductor chips are integrated into one package, the number of memory chips of the semiconductor package 10 may vary depending on applications of the semiconductor package 10. In other words, the number of memory chips of the semiconductor package 10 is not limited to the number thereof shown in the drawings.

The bridge die BD may include a base substrate and the plurality of metal pillars 110 formed on a lower surface of the base substrate. The base substrate may be a wafer including silicon (Si), for example, crystalline silicon, polycrystalline silicon, or amorphous silicon. In other words, the bridge die BD may be referred to as a silicon die. The plurality of metal pillars 110 disposed below the bridge die BD may be electrically connected with the first semiconductor chip 101 and the second semiconductor chip 102 via the redistribution layer RDL.

In some embodiments, the bridge die BD may further include a circuit region, and a buffer circuit capable of controlling capacitance loading of the first semiconductor chip 101 and the second semiconductor chip 102 may be formed in the circuit region. In some embodiments, the circuit region may include at least one selected from a transistor, a diode, a capacitor, and a resistor. In some embodiments, the bridge die BD may be an interposer.

In addition, the bridge die BD may be arranged between the first semiconductor chip 101 and the second semiconductor chip 102 and parallel to the first semiconductor chip 101 and the second semiconductor chip 102 in the first horizontal direction X. In other words, in a plan view, the bridge die BD may be arranged between the first semiconductor chip 101 and the second semiconductor chip 102.

In general semiconductor packages, when a semiconductor chip is miniaturized or the number of signal terminals for input/output increases, it is difficult to accommodate all signal terminals within a main surface of the semiconductor chip. Therefore, a redistribution layer may be extended to the outside of the main surface of the semiconductor chip to expand a region where the signal terminals are arranged. In other words, a fan-out wafer level package (FO-WLP) or fan-out panel level package (FO-PLP) (hereinafter, collectively referred to as FO-WLP) structure is applied to general semiconductor packages.

The redistribution layer RDL may include a wiring layer, a vertical via RV vertically connected to the wiring layer, and an insulating layer surrounding the wiring layer and the vertical via RV. Structurally, the vertical via RV arranged in the redistribution layer RDL may be formed to have a width in the first horizontal direction X that gradually decreases toward lower surfaces of the first semiconductor chip 101 and the second semiconductor chip 102.

A molding layer ML may be formed to surround the first semiconductor chip 101 and the second semiconductor chip 102, the bridge die BD, and the protective insulating layer 120. In some embodiments, the molding layer ML may include epoxy resin or polyimide resin. The molding layer ML may include, for example, an epoxy molding compound (EMC). In addition, the molding layer ML and the protective insulating layer 120 may include different materials from each other.

The horizontal width of the molding layer ML may be substantially the same as the horizontal width of the semiconductor package 10. In addition, side surfaces of the molding layer ML and side surfaces of the redistribution layer RDL may be coplanar with each other. In some embodiments, the molding layer ML may be formed to expose upper surfaces of the first semiconductor chip 101 and the second semiconductor chip 102 to the outside.

The external connection terminal CT may be formed on a lower surface of the redistribution layer RDL. The external connection terminal CT may include, for example, a solder ball, a conductive bump, a conductive paste, a ball grid array (BGA), a lead grid array (LGA), a pin grid array (PGA), or a combination thereof.

In the semiconductor package 10 according to an embodiment of the present disclosure, the plurality of metal pillars 110 and the redistribution layer RDL may be in electrical contact with each other and thus may be electrically connected with each other. In addition, the plurality of metal pillars 110 may include copper (Cu). In addition, a first pitch P1, which is a distance between the centers of the plurality of metal pillars 110 that are adjacent to each other, may be about 20 micrometers to about 100 micrometers. In this regard, a first separation distance D1 between the first semiconductor chip 101 and the bridge die BD and a second separation distance D2 between the second semiconductor chip 102 and the bridge die BD may each be about 10 micrometers to about 1,000 micrometers. The characteristics of the semiconductor package 10 are described in detail via a manufacturing method described below.

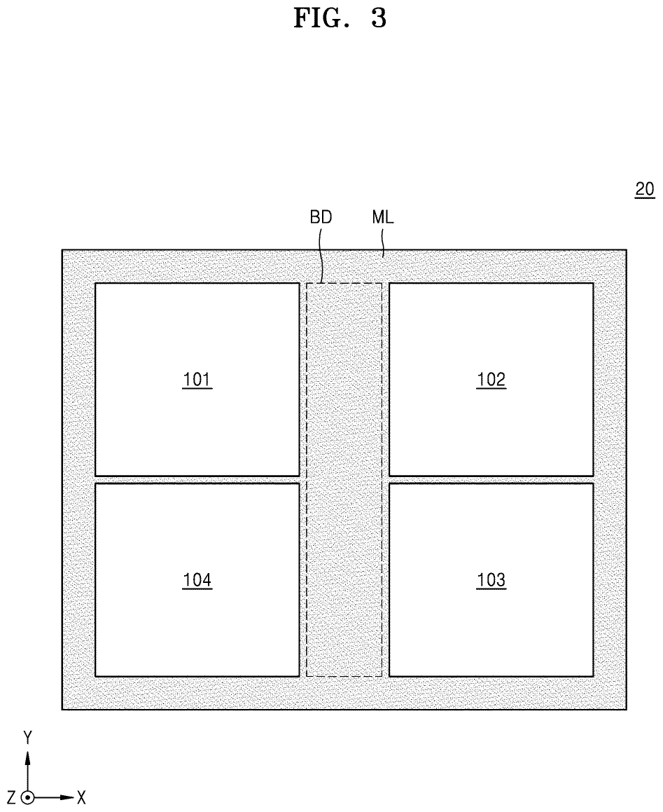

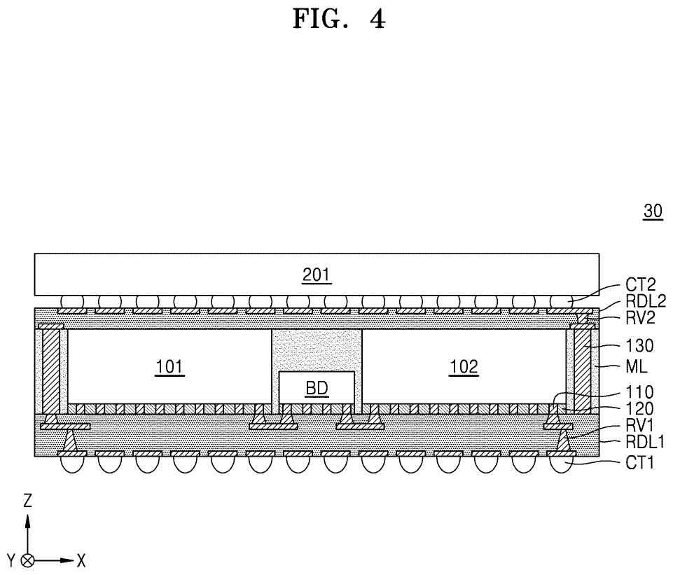

FIGS. 3 and 4 are views illustrating various embodiments of the present disclosure.

Most of components of the semiconductor package 20 and the semiconductor package 30 described below, and materials included in the components, may be substantially the same as or similar to those described with reference to FIGS. 1 and 2. Therefore, for convenience of explanation, differences from the semiconductor package 10 are mainly described.

Referring to FIG. 3, the semiconductor package 20 includes a first semiconductor chip 101, a second semiconductor chip 102, a third semiconductor chip 103, and a fourth semiconductor chip 104 arranged apart from each other in the first horizontal direction X and a second horizontal direction Y and the bridge die BD arranged therebetween. In detail, FIG. 3 is a plan view of some components of the semiconductor package 20, and a cross-sectional view thereof is omitted.

In the semiconductor package 20 of the present embodiment, each of the first semiconductor chip 101, the second semiconductor chip 102, the third semiconductor chip 103, and the fourth semiconductor chip 104 may be a memory chip, and for example, may include a volatile memory chip and/or a non-volatile memory chip. In some embodiments, the first semiconductor chip 101, the second semiconductor chip 102, the third semiconductor chip 103, and the fourth semiconductor chip 104 may be configured as a set of memory chips capable of merging data with each other.

In a plan view, the first semiconductor chip 101, the second semiconductor chip 102, the third semiconductor chip 103, and the fourth semiconductor chip 104 may be arranged in a quadrangular shape. However, in an embodiment, the number and arrangement shape of the semiconductor chips are not limited thereto.

The bridge die BD may be arranged at the center of the quadrangular shape formed by the first semiconductor chip 101, the second semiconductor chip 102, the third semiconductor chip 103, and the fourth semiconductor chip 104. In addition, the bridge die BD may be arranged parallel to each of the first semiconductor chip 101, the second semiconductor chip 102, the third semiconductor chip 103, and the fourth semiconductor chip 104 in the first horizontal direction X. In other words, in a plan view, an upper left portion of the bridge die BD may be arranged to face the first semiconductor chip 101, an upper right portion of the bridge die BD may be arranged to face the second semiconductor chip 102, a lower right portion of the bridge die BD may be arranged to face the third semiconductor chip 103, and a lower left portion of the bridge die BD may be arranged to face the fourth semiconductor chip 104.

Referring to FIG. 4, the semiconductor package 30 includes the first semiconductor chip 101 and the second semiconductor chip 102 arranged apart from each other in the first horizontal direction X, the bridge die BD arranged parallel to each of the first semiconductor chip 101 and the second semiconductor chip 102 in the first horizontal direction X, and an upper semiconductor chip 201 disposed above the first semiconductor chip 101 and the second semiconductor chip 102 to overlap the first semiconductor chip 101 and the second semiconductor chip 102 in the vertical direction Z. In detail, FIG. 4 is a cross-sectional view of main components of the semiconductor package 30, and a plan view thereof is omitted.

In the semiconductor package 30 of the present embodiment, a first redistribution layer RDL1 corresponds to the redistribution layer RDL (see FIG. 2), a first vertical via RV1 corresponds to the vertical via RV (see FIG. 2), and an external connection terminal CT1 corresponds to the external connection terminal CT (see FIG. 2).

The semiconductor package 30 of the present embodiment includes a plurality of connection posts 130 arranged around the first semiconductor chip 101 and the second semiconductor chip 102 and electrically connected with the first redistribution layer RDL1 through the molding layer ML. In addition, the semiconductor package 30 includes a second redistribution layer RDL2 formed on the molding layer ML, the plurality of connection posts 130, and the first semiconductor chip 101 and the second semiconductor chip 102. In addition, the semiconductor package 30 includes the upper semiconductor chip 201 disposed above the second redistribution layer RDL2 and electrically connected to the second redistribution layer RDL2 via an internal connection terminal CT2.

In some embodiments, the upper semiconductor chip 201 may include a logic device. For example, the upper semiconductor chip 201 may be a central processing unit chip, a graphics processing unit chip, or an application processor chip. In other words, the upper semiconductor chip 201 and the first semiconductor chip 101 and the second semiconductor chip 102 may perform different roles from each other.

The upper semiconductor chip 201 may include a semiconductor substrate having upper and lower surfaces facing away from each other, and the internal connection terminal CT2 formed on a lower surface of the semiconductor substrate. The internal connection terminal CT2 may be connected to the second redistribution layer RDL2.

The second redistribution layer RDL2 may include a wiring layer, a second vertical via RV2 vertically connected to the wiring layer, and an insulating layer surrounding the wiring layer and the second vertical via RV2. Structurally, the second vertical via RV2 arranged in the second redistribution layer RDL2 may be formed to have a width in the first horizontal direction X that gradually decreases toward upper surfaces of the first semiconductor chip 101 and the second semiconductor chip 102.

The plurality of connection posts 130 may electrically connect the redistribution layer RDL1 to the second redistribution layer RDL2 through the molding layer ML. The molding layer ML may surround the plurality of connection posts 130. The plurality of connection posts 130 may be formed around the first semiconductor chip 101 and the second semiconductor chip 102.

The upper semiconductor chip 201 may be electrically connected with the first redistribution layer RDL1 via the internal connection terminal CT2, the second redistribution layer RDL2, and the plurality of connection posts 130.

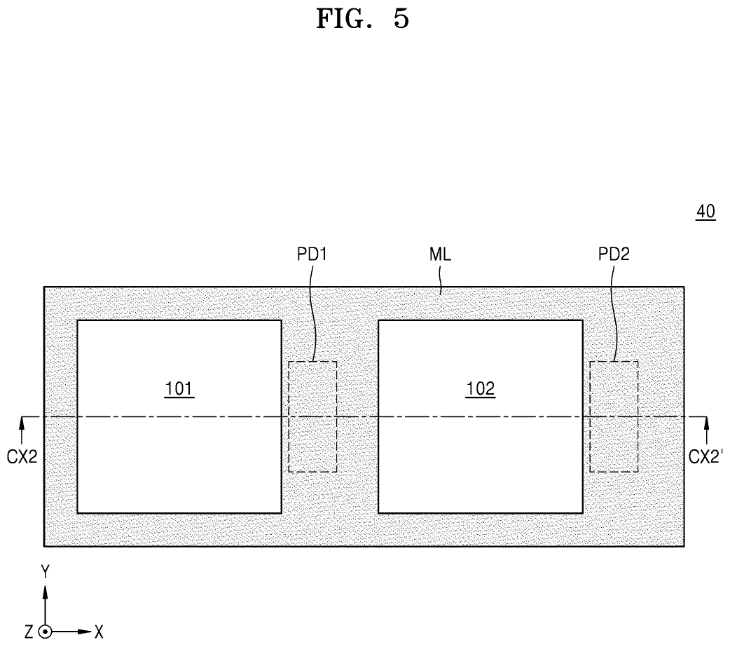

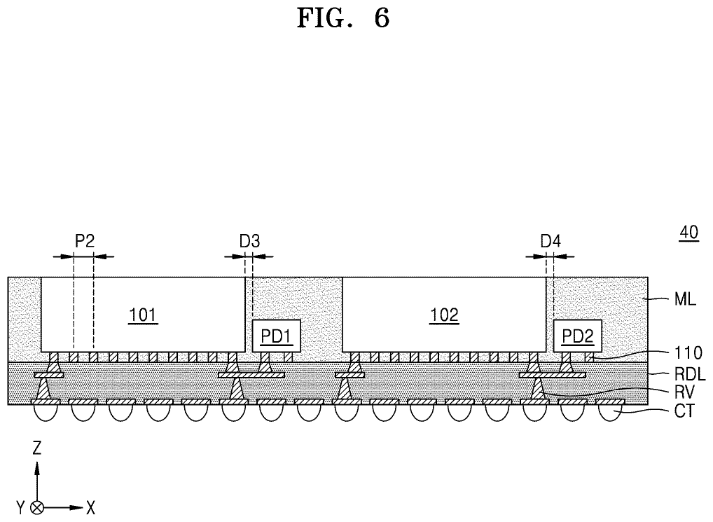

FIG. 5 is a plan view of main components of a semiconductor package according to an embodiment, and FIG. 6 is a cross-sectional view of the semiconductor package of FIG. 5 taken along line CX2-CX2′ of FIG. 5.

Referring to FIGS. 5 and 6, a semiconductor package 40 includes the first semiconductor chip 101 and the second semiconductor chip 102 arranged apart from each other in the first horizontal direction X, and a first passive device PD1 and a second passive device PD2 arranged at a side of the first semiconductor chip 101 and the second semiconductor chip 102.

Each of the first semiconductor chip 101 and the second semiconductor chip 102 may be a memory chip, and for example, may include a volatile memory chip and/or a non-volatile memory chip. In some embodiments, the first semiconductor chip 101 and the second semiconductor chip 102 may be configured as a set of memory chips capable of merging data with each other.

Each of the first semiconductor chip 101 and the second semiconductor chip 102 may include a semiconductor substrate having upper and lower surfaces facing away from each other, and the plurality of metal pillars 110 formed on a lower surface of the semiconductor substrate.

Some of the plurality of metal pillars 110 disposed below the first semiconductor chip 101 and the second semiconductor chip 102 may be connected to the external connection terminal CT via the redistribution layer RDL. In addition, the others of the plurality of metal pillars 110 disposed below the first semiconductor chip 101 and the second semiconductor chip 102 may be connected to the first passive device PD1 and the second passive device PD2 via the redistribution layer RDL.

Each of the first passive device PD1 and the second passive device PD2 may include a base substrate and the plurality of metal pillars 110 formed on a lower surface of the base substrate. The base substrate may be a wafer including silicon (Si), for example, crystalline silicon, polycrystalline silicon, or amorphous silicon. In other words, each of the first passive device PD1 and the second passive device PD2 may be referred to as a silicon die. The plurality of metal pillars 110 disposed below the first passive device PD1 and the second passive device PD2 may be electrically connected with a corresponding one of the first semiconductor chip 101 and the second semiconductor chip 102 via the redistribution layer RDL. For example, the plurality of metal pillars 110 disposed below the first passive device PD1 may be electrically connected to the first semiconductor chip 101 via the redistribution layer RDL, and the plurality of metal pillars 110 disposed below the second passive device PD2 may be electrically connected to the second semiconductor chip 102 via the redistribution layer RDL.

In some embodiments, each of the first passive device PD1 and the second passive device PD2 may include at least one selected from a resistor, a capacitor, an inductor, a thermistor, an oscillator, a ferrite bead, an antenna, and a varistor. For example, each of the first passive device PD1 and the second passive device PD2 may include a multilayer ceramic capacitor (MLCC), a low inductance chip capacitor (LICC), a land side capacitor (LSC), or an integrated passive device (IPD), but is not limited thereto.

In addition, the first passive device PD1 and the second passive device PD2 may be arranged around the corresponding one from among the first semiconductor chip 101 and the second semiconductor chip 102, and parallel to the first semiconductor chip 101 and the second semiconductor chip 102 in the first horizontal direction X. In other words, in a plan view, the first passive device PD1 may be arranged to face the first semiconductor chip 101, and the second passive device PD2 may be arranged to face the second semiconductor chip 102.

The redistribution layer RDL may include a wiring layer, the vertical via RV vertically connected to the wiring layer, and an insulating layer surrounding the wiring layer and the vertical via RV. Structurally, the vertical via RV arranged in the redistribution layer RDL may be formed to have a width in the first horizontal direction X that gradually decreases toward lower surfaces of the first semiconductor chip 101 and the second semiconductor chip 102.

The molding layer ML may be formed to surround the first semiconductor chip 101 and the second semiconductor chip 102, the first passive device PD1 and the second passive device PD2, and the plurality of metal pillars 110. In some embodiments, the molding layer ML may include epoxy resin or polyimide resin. The molding layer ML may include, for example, an epoxy molding compound.

The horizontal width of the molding layer ML may be substantially the same as the horizontal width of the semiconductor package 40. In addition, side surfaces of the molding layer ML and side surfaces of the redistribution layer RDL may be coplanar with each other. In some embodiments, the molding layer ML may be formed to expose upper surfaces of the first semiconductor chip 101 and the second semiconductor chip 102 to the outside.

The external connection terminal CT may be formed on a lower surface of the redistribution layer RDL. The external connection terminal CT may include, for example, a solder ball, a conductive bump, a conductive paste, a BGA, an LGA, a PGA, or a combination thereof.

In the semiconductor package 40 according to an embodiment of the present disclosure, the plurality of metal pillars 110 and the redistribution layer RDL may be in electrical contact with each other and thus may be electrically connected with each other. In addition, the plurality of metal pillars 110 may include copper (Cu). In addition, a second pitch P2, which is a distance between the centers of the plurality of metal pillars 110 that are adjacent to each other, may be about 20 micrometers to about 100 micrometers. In this regard, a third separation distance D3 between the first semiconductor chip 101 and the first passive device PD1 and a fourth separation distance D4 between the second semiconductor chip 102 and the second passive device PD2 may each be about 10 micrometers to about 1,000 micrometers. The characteristics of the semiconductor package 40 are described in detail via a manufacturing method described below.

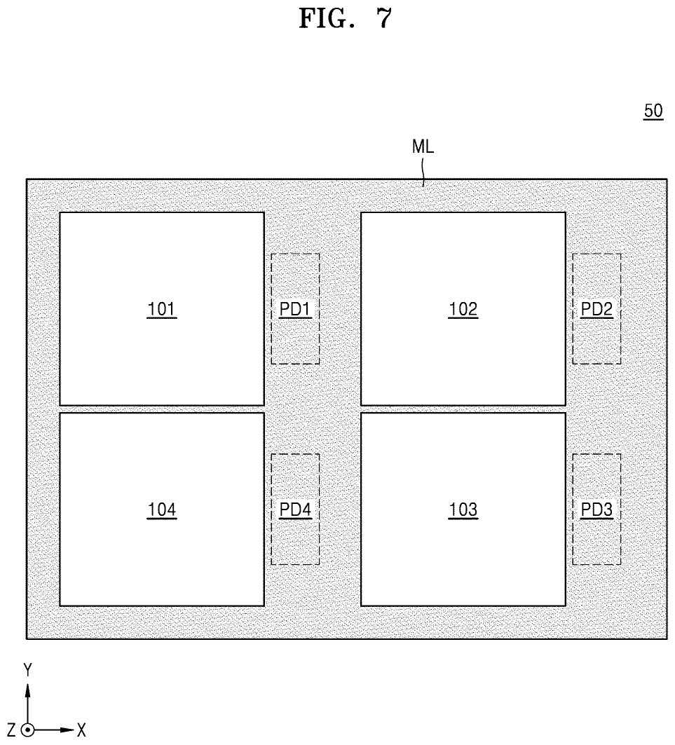

FIG. 7 is a plan view illustrating an embodiment of the present disclosure.

Most of components of a semiconductor package 50 described below and materials included in the components may be substantially the same as or similar to those described with reference to FIGS. 5 and 6. Therefore, for convenience of explanation, differences from the semiconductor package 40 are mainly described.

Referring to FIG. 7, the semiconductor package 50 is shown that includes the first semiconductor chip 101, the second semiconductor chip 102, the third semiconductor chip 103, and the fourth semiconductor chip 104 arranged apart from each other in the first horizontal direction X and the second horizontal direction Y, and a first passive device PD1, a second passive device PD2, a third passive device PD3, and a fourth passive device PD4 arranged at a side of the first semiconductor chip 101, the second semiconductor chip 102, the third semiconductor chip 103, and the fourth semiconductor chip 104, respectively. In detail, FIG. 7 is a plan view of some components of the semiconductor package 50, and a cross-sectional view thereof is omitted.

In the semiconductor package 50 of the present embodiment, each of the first semiconductor chip 101, the second semiconductor chip 102, the third semiconductor chip 103, and the fourth semiconductor chip 104 may be a memory chip, and for example, may include a volatile memory chip and/or a non-volatile memory chip. In some embodiments, the first semiconductor chip 101, the second semiconductor chip 102, the third semiconductor chip 103, and the fourth semiconductor chip 104 may be configured as a set of memory chips capable of merging data with each other.

In a plan view, the first semiconductor chip 101, the second semiconductor chip 102, the third semiconductor chip 103, and the fourth semiconductor chip 104 may be arranged in a quadrangular shape. However, in an embodiment, the number and arrangement shape of the semiconductor chips are not limited thereto.

The first passive device PD1, the second passive device PD2, the third passive device PD3, and the fourth passive device PD4 may be respectively arranged on the right side of the first semiconductor chip 101, the second semiconductor chip 102, the third semiconductor chip 103, and the fourth semiconductor chip 104. In addition, the first passive device PD1, the second passive device PD2, the third passive device PD3, and the fourth passive device PD4 may be respectively arranged parallel to the corresponding one from among the first semiconductor chip 101, the second semiconductor chip 102, the third semiconductor chip 103, and the fourth semiconductor chip 104 in the first horizontal direction X. In other words, in a plan view, the first passive device PD1 may be arranged to face the first semiconductor chip 101, the second passive device PD2 may be arranged to face the second semiconductor chip 102, the third passive device PD3 may be arranged to face the third semiconductor chip 103, and the fourth passive device PD4 may be arranged to face the fourth semiconductor chip 104.

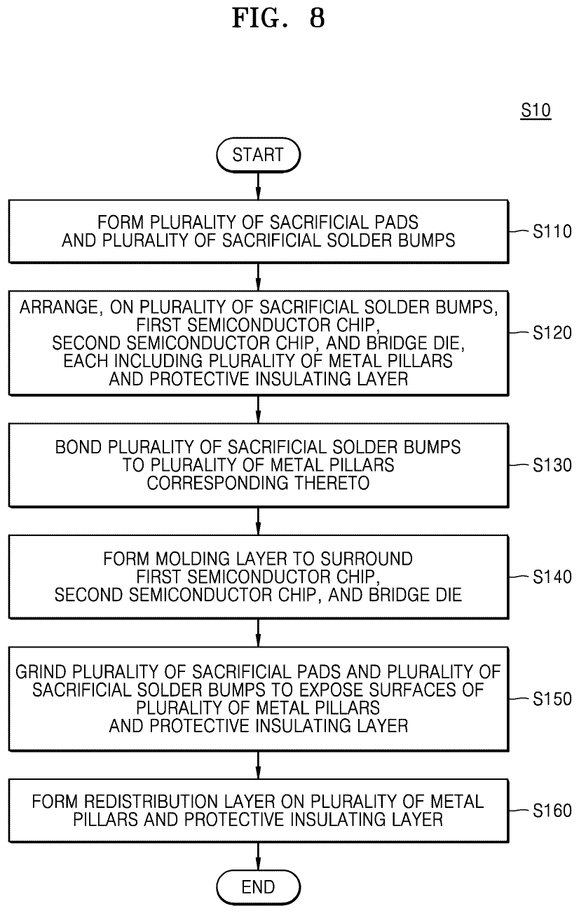

FIG. 8 is a flowchart illustrating a method of manufacturing a semiconductor package, according to an embodiment.

Referring to FIG. 8, a method S10 of manufacturing a semiconductor package may include a process order of first to sixth operations S110 to S160.

When a certain embodiment is implemented differently, a specific process order may be performed differently from the described order. For example, two consecutively described processes may be performed substantially at the same time or performed in an order opposite to the described order.

The method S10 of manufacturing the semiconductor package according to an embodiment of the present disclosure may include: the first operation S110 of forming a plurality of sacrificial pads and a plurality of sacrificial solder bumps; the second operation S120 of arranging, on the plurality of sacrificial solder bumps, a first semiconductor chip, a second semiconductor chip, and a bridge die, each including a plurality of metal pillars and a protective insulating layer thereon; the third operation S130 of bonding the plurality of sacrificial solder bumps to the plurality of metal pillars corresponding thereto; the fourth operation S140 of forming a molding layer to surround the first semiconductor chip, the second semiconductor chip, and the bridge die; the fifth operation S150 of grinding the plurality of sacrificial pads and the plurality of sacrificial solder bumps to expose surfaces of the plurality of metal pillars and protective insulating layer; and the sixth operation S160 of forming a redistribution layer on the plurality of metal pillars and the protective insulating layer.

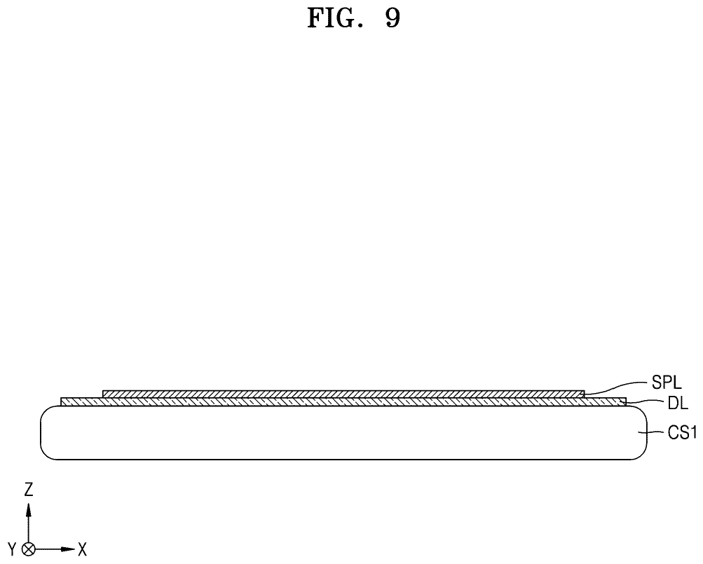

Technical features of the first to sixth operations S110 to S160 are described in detail below with reference to FIGS. 9 to 17.

FIGS. 9 to 17 are cross-sectional views illustrating, in a process order, a method of manufacturing a semiconductor package, according to an embodiment.

Referring to FIG. 9, an adhesive insulating layer DL may be attached onto a first carrier substrate CS1, and a sacrificial pad layer SPL may be formed on the adhesive insulating layer DL.

The first carrier substrate CS1 may include, for example, glass, silicon, or aluminum oxide. The adhesive insulating layer DL may include any material capable of fixing the sacrificial pad layer SPL. The adhesive insulating layer DL may be, for example, an adhesive tape of which adhesion is weakened by heat treatment or by laser irradiation. The sacrificial pad layer SPL may be a conductive layer including copper (Cu).

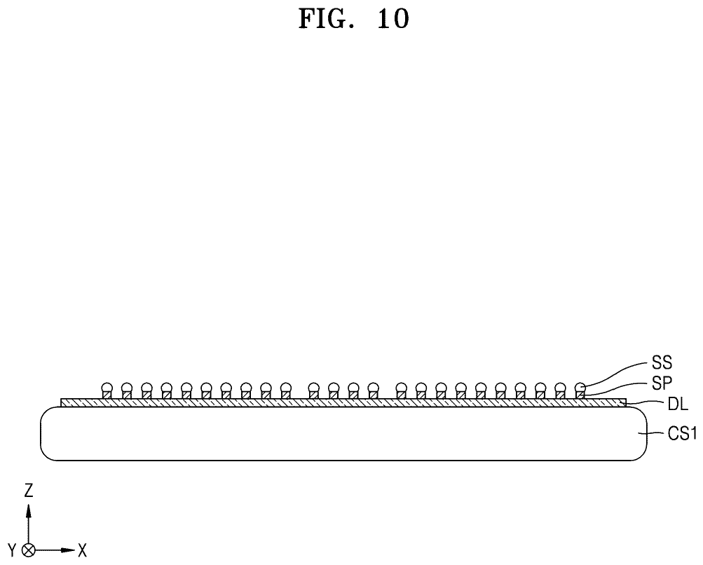

Referring to FIG. 10, a plurality of sacrificial pads SP may be formed on the sacrificial pad layer SPL (see FIG. 9) via patterning by a photolithography process and an etching process.

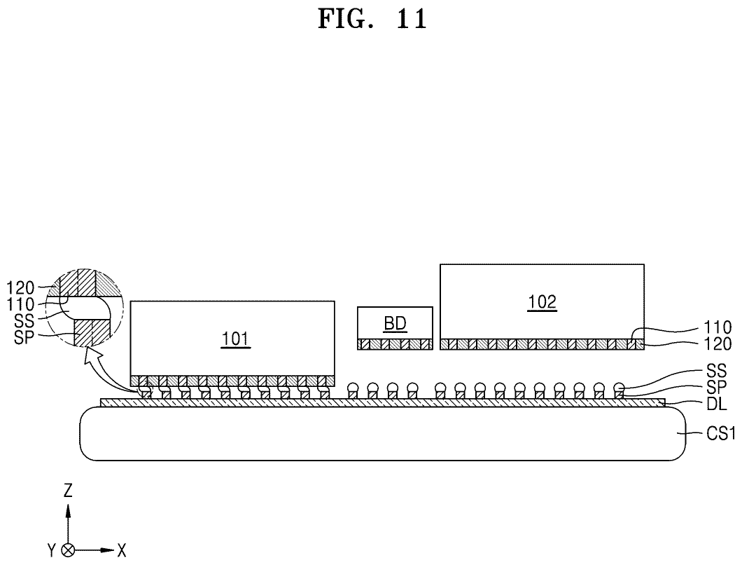

The plurality of sacrificial pads SP may be formed to have fine gaps between each other. For example, the plurality of sacrificial pads SP may be formed to have a pitch of about 20 micrometers to about 100 micrometers, but is not limited thereto. The plurality of sacrificial pads SP may be formed in a region where the first semiconductor chip 101 and the second semiconductor chip 102 (see FIG. 11) and the bridge die BD (see FIG. 11) are mounted.

Next, a plurality of sacrificial solder bumps SS may be formed on the plurality of sacrificial pads SP. The plurality of sacrificial solder bumps SS may be leaded solder including tin (Sn) and lead (Pb) or lead-free solder including tin (Sn) but not lead (Pb).

Referring to FIG. 11, the first semiconductor chip 101, the second semiconductor chip 102, and the bridge die BD, each including thereon the plurality of metal pillars 110 and the protective insulating layer 120 surrounding side surfaces of the plurality of metal pillars 110, may be disposed on the plurality of sacrificial solder bumps SS and parallel to each other.

First, the plurality of sacrificial solder bumps SS and the plurality of metal pillars 110 corresponding thereto may be in contact with each other between the first semiconductor chip 101 and the first carrier substrate CS1. In this case, as shown in the drawing, the central axes of the plurality of metal pillars 110 and the central axes of the plurality of sacrificial pads SP may be arranged to be offset from each other with the plurality of sacrificial solder bumps SS therebetween. This may be due to errors occurring during an alignment process of fine patterns.

Next, the plurality of sacrificial solder bumps SS and the plurality of metal pillars 110 corresponding thereto may be in contact with each other between the bridge die BD and the first carrier substrate CS1. In this regard, the first semiconductor chip 101 and the bridge die BD may be arranged to have a separation distance of about 10 micrometers to about 1,000 micrometers.

Next, the plurality of sacrificial solder bumps SS and the plurality of metal pillars 110 corresponding thereto may be in contact with each other between the second semiconductor chip 102 and the first carrier substrate CS1. In this regard, the bridge die BD and the second semiconductor chip 102 may be arranged to have a separation distance of about 10 micrometers to about 1,000 micrometers.

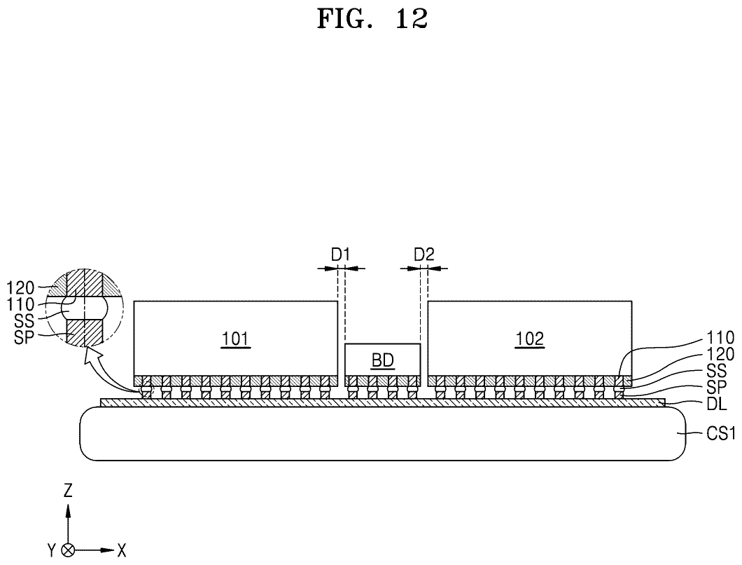

Referring to FIG. 12, a reflow process may be performed on the plurality of sacrificial solder bumps SS to self-align the plurality of metal pillars 110 and the plurality of sacrificial pads SP with each other.

The plurality of sacrificial solder bumps SS may be melted by the reflow process. In this case, as shown in the drawing, due to the surface tension of the melted plurality of sacrificial solder bumps SS, the central axes of the plurality of metal pillars 110 and the central axes of the plurality of sacrificial pads SP may be aligned to coincide with each other with the plurality of sacrificial solder bumps SS therebetween. In other words, without using an additional process, the plurality of metal pillars 110 and the plurality of sacrificial pads SP may be aligned without errors. In addition, because the protective insulating layer 120 surrounds the plurality of metal pillars 110, a phenomenon in which the plurality of sacrificial solder bumps SS are melted and excessively overflow to sidewalls of the plurality of metal pillars 110 may be prevented.

Using this self-alignment, the first separation distance D1 between the first semiconductor chip 101 and the bridge die BD and the second separation distance D2 between the second semiconductor chip 102 and the bridge die BD may both be relatively small (for example, about 10 micrometers to about 1,000 micrometers).

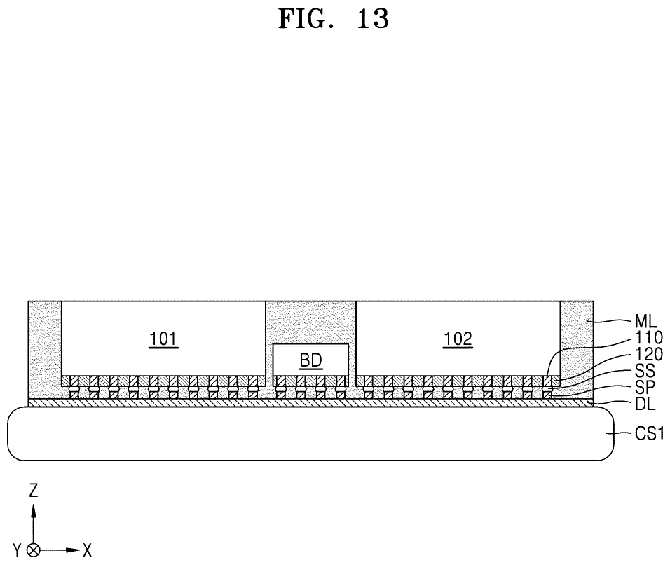

Referring to FIG. 13, the molding layer ML may be formed to surround side surfaces of the first semiconductor chip 101 and the second semiconductor chip 102 and side surfaces of the bridge die BD.

In detail, the molding layer ML may be formed on the adhesive insulating layer DL to surround the first semiconductor chip 101 and the second semiconductor chip 102, the bridge die BD, a plurality of protective insulating layers 120, the plurality of sacrificial solder bumps SS, and the plurality of sacrificial pads SP. The molding layer ML may serve to protect the first semiconductor chip 101, the second semiconductor chip 102, and the bridge die BD from external influences such as shock and contamination.

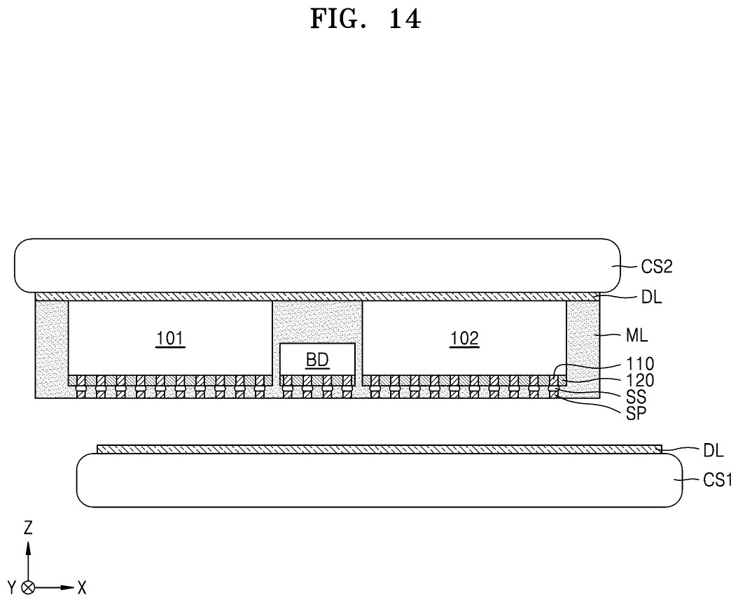

Referring to FIG. 14, a second carrier substrate CS2 may be attached onto the first semiconductor chip 101 and the second semiconductor chip 102 to face the first carrier substrate CS1.

The second carrier substrate CS2 may be attached to remove the first carrier substrate CS1 and perform a subsequent process. The second carrier substrate CS2 may include, for example, glass, silicon, or aluminum oxide.

In some embodiments, a laser beam may be irradiated to the first carrier substrate CS1 to separate the first carrier substrate CS1. Due to the irradiation of the laser beam, a bonding force between the adhesive insulating layer DL and the first carrier substrate CS1 may be weakened. In some embodiments, heat may be applied to the adhesive insulating layer DL on the first carrier substrate CS1.

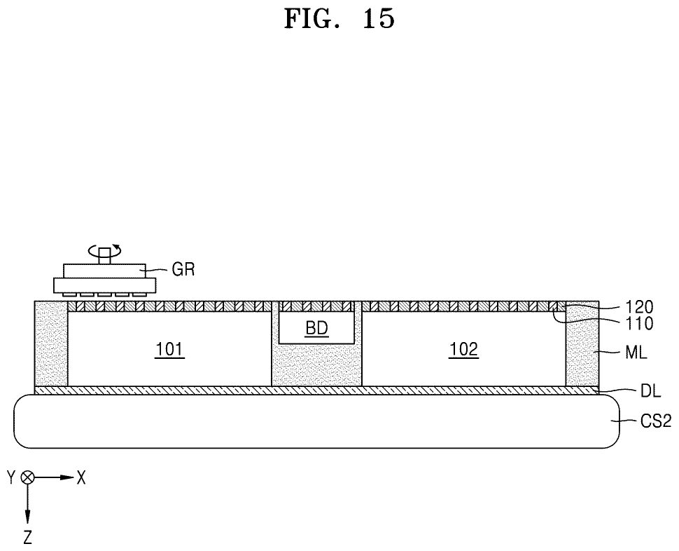

Referring to FIG. 15, the second carrier substrate CS2 may be turned over, and a portion of the molding layer ML, the plurality of sacrificial pads SP (see FIG. 14), and the plurality of sacrificial solder bumps SS (see FIG. 14) may be removed, to expose the plurality of metal pillars 110 and the plurality of protective insulating layers 120.

A grinding and flattening process is performed using a grinder GR. The grinding and flattening process may be a chemical mechanical grinding process. The grinder GR may remove a portion of the molding layer ML, the plurality of sacrificial pads SP (see FIG. 13), and the plurality of sacrificial solder bumps SS (see FIG. 13), such that an upper surface of the molding layer ML, upper surfaces of the plurality of metal pillars 110, and upper surfaces of the plurality of protective insulating layers 120 may be formed as one flat surface.

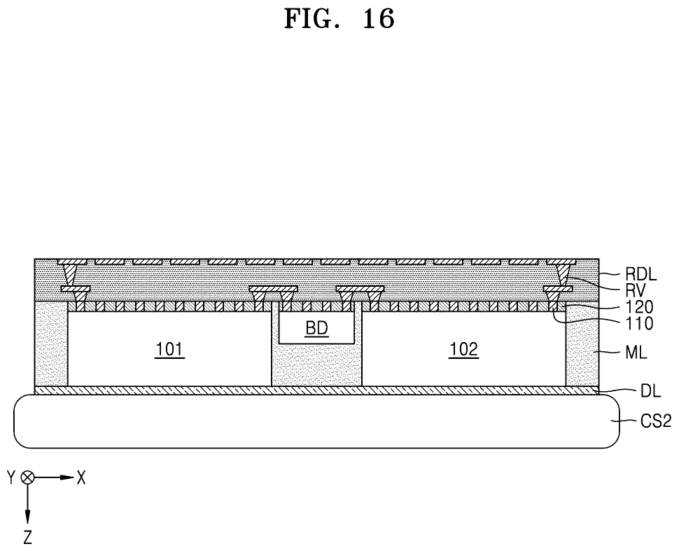

Referring to FIG. 16, the redistribution layer RDL may be formed on the molding layer ML, the plurality of metal pillars 110, and the plurality of protective insulating layers 120, each having a flat surface via the grinding and flattening process.

The redistribution layer RDL may include a wiring layer, the vertical via RV vertically connected to the wiring layer, and an insulating layer surrounding the wiring layer and the vertical via RV. A lower surface of the redistribution layer RDL and upper surfaces of the plurality of metal pillars 110 may be in direct contact with each other, and the lower surface of the redistribution layer RDL and upper surfaces of the plurality of protective insulating layers 120 may be in direct contact with each other.

In this regard, according to a process for forming the vertical via RV, structurally, the vertical via RV arranged in the redistribution layer RDL may be formed to have a width in the first horizontal direction X that gradually decreases toward lower surfaces of the first semiconductor chip 101 and the second semiconductor chip 102.

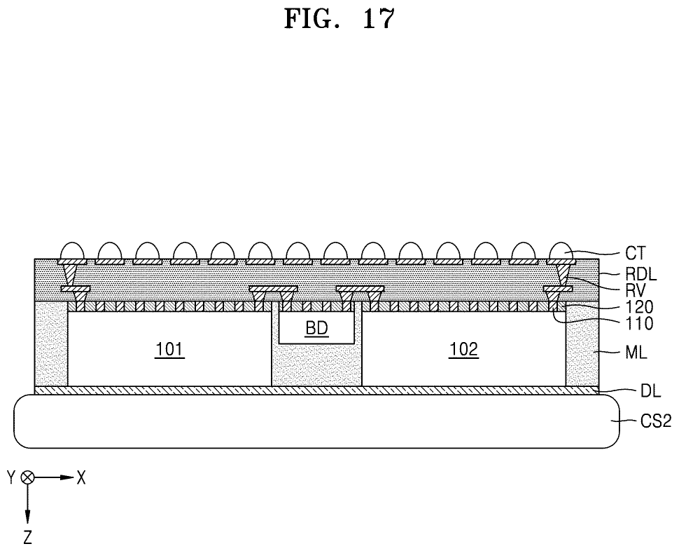

Referring to FIG. 17, the external connection terminal CT may be formed on an upper surface of the redistribution layer RDL.

The external connection terminal CT may include, for example, a solder ball, a conductive bump, a conductive paste, a BGA, an LGA, a PGA, or a combination thereof. The external connection terminal CT may be formed on a distribution pad connected with the wiring layer of the redistribution layer RDL.

Referring back to FIG. 2, the second carrier substrate CS2 may be turned over, and the second carrier substrate CS2 may be separated. In some embodiments, a laser beam may be irradiated to the adhesive insulating layer DL on the second carrier substrate CS2. In some embodiments, heat may be applied to the adhesive insulating layer DL on the second carrier substrate CS2.

As described above, according to the method of manufacturing a semiconductor package according to an embodiment of the present disclosure, by self-aligning the first semiconductor chip 101, the second semiconductor chip 102, and the bridge die BD on pads having fine gaps due to the surface tension of solder bumps, distances between the first semiconductor chip 101 and the second semiconductor chip 102 and the bridge die BD may be minimized, thereby reducing the size of the semiconductor package 10.

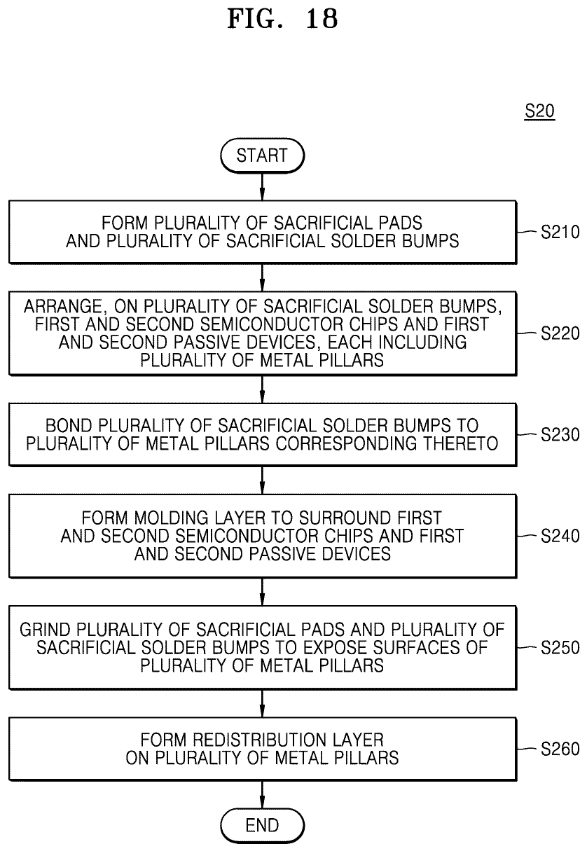

FIG. 18 is a flowchart illustrating a method of manufacturing a semiconductor package, according to another embodiment.

Referring to FIG. 18, a method S20 of manufacturing a semiconductor package may include a process order of first to sixth operations S210 to S260.

When a certain embodiment is implemented differently, a specific process order may be performed differently from the described order. For example, two consecutively described processes may be performed substantially at the same time or performed in an order opposite to the described order.

A method S20 of manufacturing a semiconductor package according to an embodiment of the present disclosure may include: a first operation S210 of forming a plurality of sacrificial pads and a plurality of sacrificial solder bumps; a second operation S220 of arranging, on the plurality of sacrificial solder bumps, first and second semiconductor chips and first and second passive devices, each including a plurality of metal pillars thereon; a third operation S230 of bonding the plurality of sacrificial solder bumps to the plurality of metal pillars corresponding thereto; a fourth operation S240 of forming a molding layer to surround the first and second semiconductor chips and the first and second passive devices; a fifth operation S250 of grinding the plurality of sacrificial pads and the plurality of sacrificial solder bumps to expose surfaces of the plurality of metal pillars; and a sixth operation S260 of forming a redistribution layer on the plurality of metal pillars.

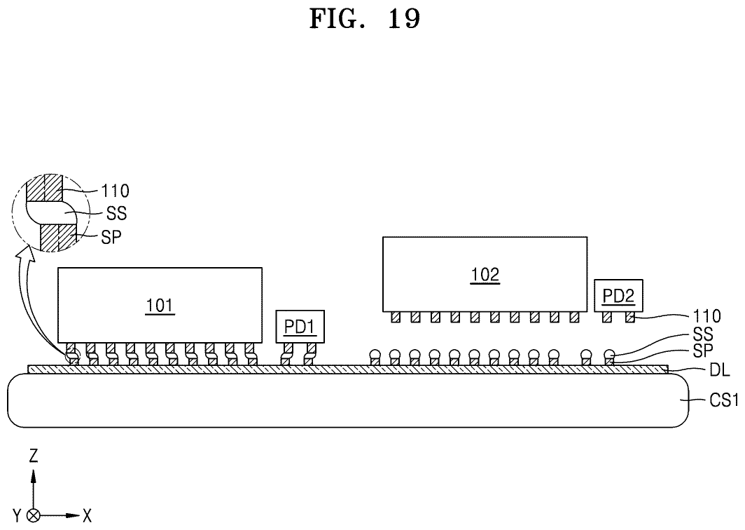

Technical features of the first to sixth operations S210 to S260 are described in detail below with reference to FIGS. 19 to 25.

FIGS. 19 to 25 are cross-sectional views illustrating, in a process order, a method of manufacturing a semiconductor package, according to an embodiment.

Referring to FIG. 19, the manufacturing operations of FIGS. 9 and 10 described above may be performed in the same manner to prepare the first carrier substrate CS1 on which the plurality of sacrificial solder bumps SS are formed on the plurality of sacrificial pads SP.

Next, the first semiconductor chip 101 and the second semiconductor chip 102, each including thereon some of the plurality of metal pillars 110, and the first passive device PD1 and the second passive device PD2, each including thereon others of the plurality of metal pillars 110, may be arranged parallel to each other on the plurality of sacrificial solder bumps SS.

First, the plurality of sacrificial solder bumps SS and the plurality of metal pillars 110 corresponding thereto may be in contact with each other between the first semiconductor chip 101 and the first passive device PD1 corresponding thereto and the first carrier substrate CS1. In this case, as shown in the drawing, the central axes of the plurality of metal pillars 110 and the central axes of the plurality of sacrificial pads SP may be arranged to be offset from each other with the plurality of sacrificial solder bumps SS therebetween. This may be due to errors occurring during an alignment process of fine patterns. In this regard, the first semiconductor chip 101 and the first passive device PD1 may be arranged to have a separation distance of about 10 micrometers to about 1,000 micrometers.

Next, the plurality of sacrificial solder bumps SS and the plurality of metal pillars 110 corresponding thereto may be in contact with each other between each of the second semiconductor chip 102 and the second passive device PD2 corresponding thereto and the first carrier substrate CS1. In this regard, the second semiconductor chip 102 and the second passive device PD2 may be arranged to have a separation distance of about 10 micrometers to about 1,000 micrometers.

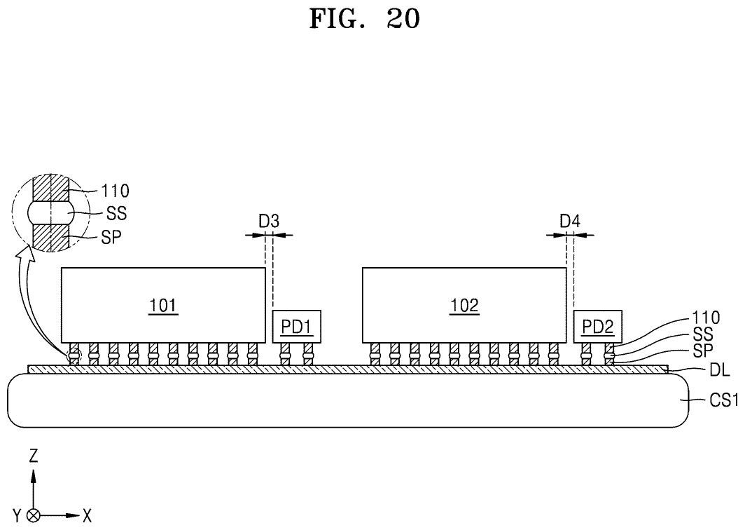

Referring to FIG. 20, a reflow process is performed on the plurality of sacrificial solder bumps SS to self-align the plurality of metal pillars 110 and the plurality of sacrificial pads SP with each other.

The plurality of sacrificial solder bumps SS may be melted by the reflow process. In this case, as shown in the drawing, due to the surface tension of the melted plurality of sacrificial solder bumps SS, the central axes of the plurality of metal pillars 110 and the central axes of the plurality of sacrificial pads SP may be aligned to coincide with each other with the plurality of sacrificial solder bumps SS therebetween. In other words, without using an additional process, the plurality of metal pillars 110 and the plurality of sacrificial pads SP may be aligned without errors.

Using this self-alignment, the third separation distance D3 between the first semiconductor chip 101 and the first passive device PD1 and the fourth separation distance D4 between the second semiconductor chip 102 and the second passive device PD2 may both be relatively small (for example, about 10 micrometers to about 1,000 micrometers).

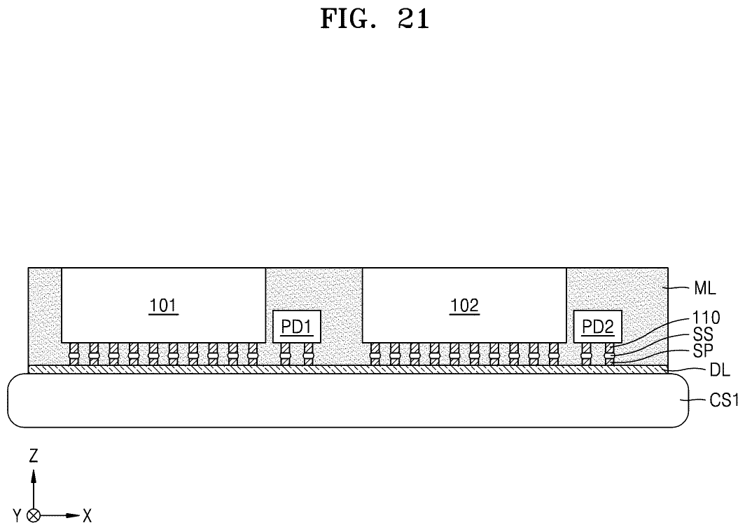

Referring to FIG. 21, the molding layer ML may be formed to surround side surfaces of the first semiconductor chip 101 and the second semiconductor chip 102 and side surfaces of the first passive device PD1 and the second passive device PD2.

In detail, the molding layer ML may be formed on the adhesive insulating layer DL to surround the first semiconductor chip 101, the second semiconductor chip 102, the first passive device PD1, the second passive device PD2, the plurality of metal pillars 110, the plurality of sacrificial solder bumps SS, and the plurality of sacrificial pads SP. The molding layer ML may serve to protect the first semiconductor chip 101, the second semiconductor chip 102, the first passive device PD1, and the second passive device PD2 from external influences such as shock and contamination.

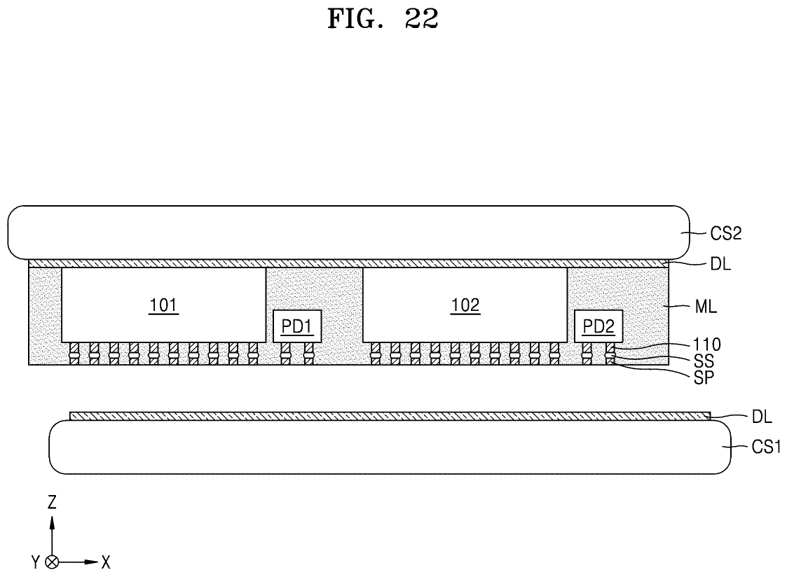

Referring to FIG. 22, the second carrier substrate CS2 may be attached onto the first semiconductor chip 101 and the second semiconductor chip 102 to face the first carrier substrate CS1.

The second carrier substrate CS2 may be attached to remove the first carrier substrate CS1 and perform a subsequent process. The second carrier substrate CS2 may include, for example, glass, silicon, or aluminum oxide.

In some embodiments, a laser beam may be irradiated to the first carrier substrate CS1 to separate the first carrier substrate CS1. Due to the irradiation of the laser beam, a bonding force between the adhesive insulating layer DL and the first carrier substrate CS1 may be weakened. In some embodiments, heat may be applied to the adhesive insulating layer DL on the first carrier substrate CS1.

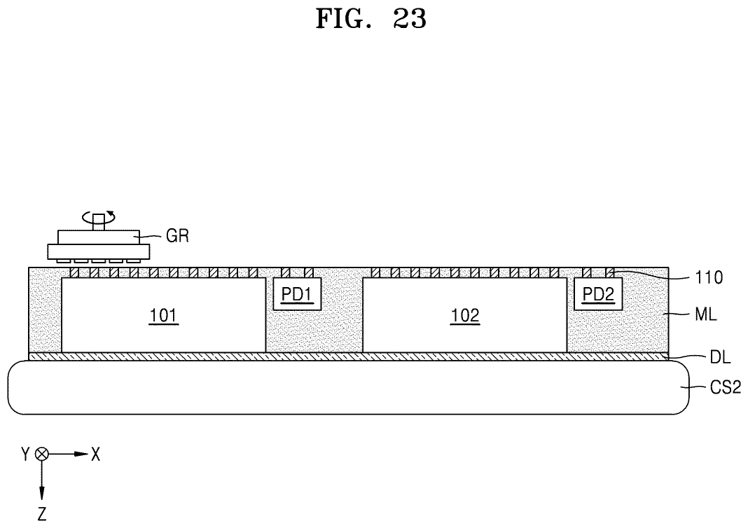

Referring to FIG. 23, the second carrier substrate CS2 may be turned over, and a portion of the molding layer ML, the plurality of sacrificial pads SP (see FIG. 22), and the plurality of sacrificial solder bumps SS (see FIG. 22) may be removed, to expose the plurality of metal pillars 110.

A grinding and flattening process is performed using the grinder GR. The grinding and flattening process may be a chemical mechanical grinding process. The grinder GR may remove a portion of the molding layer ML, the plurality of sacrificial pads SP (see FIG. 22), and the plurality of sacrificial solder bumps (see FIG. 22), such that an upper surface of the molding layer ML and upper surfaces of the plurality of metal pillars 110 may be formed as one flat surface.

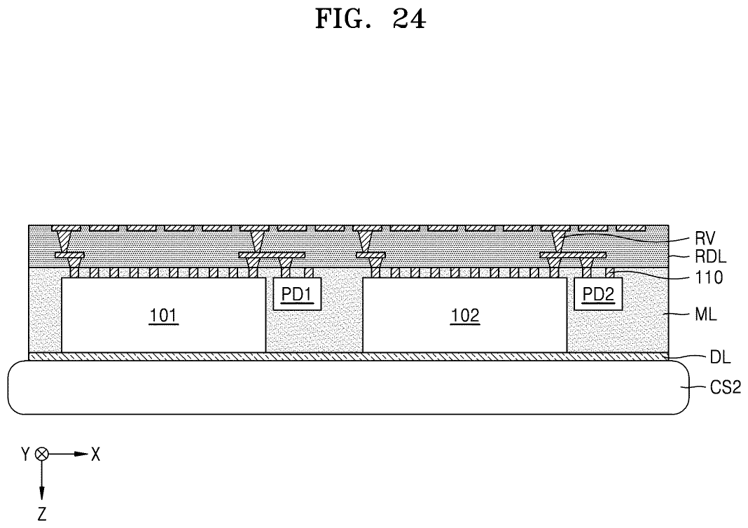

Referring to FIG. 24, the redistribution layer RDL may be formed on the molding layer ML and the plurality of metal pillars 110, each having a flat surface via the grinding and flattening process.

The redistribution layer RDL may include a wiring layer, the vertical via RV vertically connected to the wiring layer, and an insulating layer surrounding the wiring layer and the vertical via RV. A lower surface of the redistribution layer RDL and upper surfaces of the plurality of metal pillars 110 may be in direct contact with each other.

In this regard, according to a process for forming the vertical via RV, structurally, the vertical via RV arranged in the redistribution layer RDL may be formed to have a width in the first horizontal direction X that gradually decreases toward lower surfaces of the first semiconductor chip 101 and the second semiconductor chip 102.

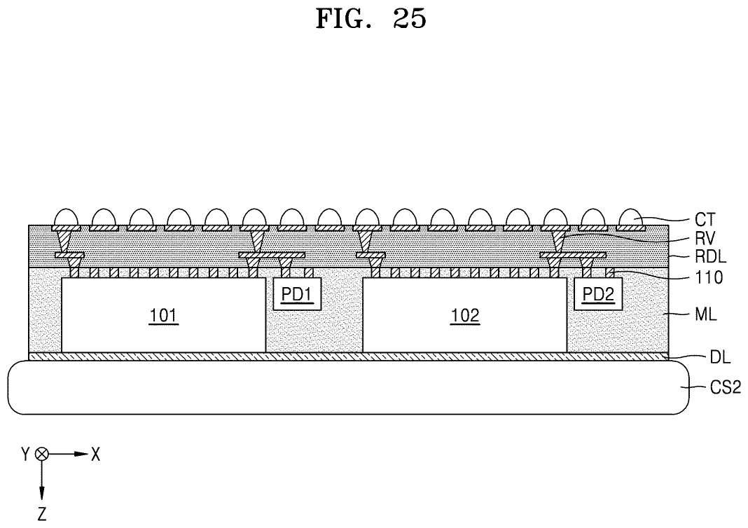

Referring to FIG. 25, the external connection terminal CT may be formed on an upper surface of the redistribution layer RDL.

The external connection terminal CT may include, for example, a solder ball, a conductive bump, a conductive paste, a BGA, an LGA, a PGA, or a combination thereof. The external connection terminal CT may be formed on a distribution pad connected with the wiring layer of the redistribution layer RDL.

Referring back to FIG. 6, the second carrier substrate CS2 may be turned over, and the second carrier substrate CS2 may be separated. In some embodiments, a laser beam may be irradiated to the adhesive insulating layer DL on the second carrier substrate CS2. In some embodiments, heat may be applied to the adhesive insulating layer DL on the second carrier substrate CS2.

As described above, according to the method of manufacturing a semiconductor package according to an embodiment of the present disclosure, by self-aligning the first semiconductor chip 101 and the second semiconductor chip 102 and the first passive device PD1 and the second passive device PD2 corresponding thereto on pads having fine gaps due to the surface tension of solder bumps, distances between the first semiconductor chip 101, the second semiconductor chip 102, the first passive device PD1, and the second passive device PD2 may be minimized, thereby reducing the size of the semiconductor package 40.

While non-limiting example embodiments of the present disclosure have been particularly shown and described, it will be understood that various changes in form and details may be made therein without departing from the spirit and scope of the present disclosure.

What is claimed is:

1. A method of manufacturing a semiconductor package, the method comprising:
forming a plurality of sacrificial pads on a first carrier substrate;
forming a plurality of sacrificial solder bumps on the plurality of sacrificial pads;
arranging, on the plurality of sacrificial solder bumps, a first semiconductor chip, a second semiconductor chip, and a bridge die that are spaced apart from each other in a horizontal direction, each of the first semiconductor chip, the second semiconductor chip, and the bridge die comprising a lower surface on which a plurality of metal pillars and a protective insulating layer surrounding side surfaces of the plurality of metal pillars are provided;
bonding the plurality of sacrificial solder bumps to the plurality of metal pillars that are on the lower surface of each of the first semiconductor chip, the second semiconductor chip, and the bridge die, such that the plurality of sacrificial solder bumps is between the first carrier substrate and each of the first semiconductor chip, the second semiconductor chip, and the bridge die;
forming a molding layer that surrounds the plurality of sacrificial pads, the plurality of sacrificial solder bumps, the protective insulating layer, the first semiconductor chip, the second semiconductor chip, and the bridge die;
attaching a second carrier substrate onto the first semiconductor chip and the second semiconductor chip, and removing the first carrier substrate;
exposing surfaces of the plurality of metal pillars and a surface of the protective insulating layer by grinding and removing all of the plurality of sacrificial pads and the plurality of sacrificial solder bumps;
forming a redistribution layer on the plurality of metal pillars and the protective insulating layer;
forming an external connection terminal on the redistribution layer; and
removing the second carrier substrate.

2. The method of claim 1, wherein the bonding the plurality of sacrificial solder bumps to the plurality of metal pillars comprises self-aligning the plurality of metal pillars and the plurality of sacrificial pads with each other, due to surface tension of the plurality of sacrificial solder bumps, by performing a reflow process on the plurality of sacrificial solder bumps.

3. The method of claim 1, wherein the plurality of metal pillars and the plurality of sacrificial pads each comprise copper (Cu), and
the plurality of metal pillars and the redistribution layer are in direct contact with each other and are electrically connected with each other.

4. The method of claim 3, wherein an interface between the molding layer and the redistribution layer and an interface between the protective insulating layer and the redistribution layer are coplanar with each other, and
the molding layer and the protective insulating layer comprise different materials from each other.

5. The method of claim 4, wherein a pitch of the plurality of metal pillars is about 20 micrometers to about 100 micrometers, and
a separation distance between the first semiconductor chip and the bridge die and a separation distance between the second semiconductor chip and the bridge die are each about 10 micrometers to about 1,000 micrometers.

6. The method of claim 1, wherein the redistribution layer comprises a vertical via has a width in the horizontal direction that gradually decreases toward the lower surface of the first semiconductor chip or the lower surface of the second semiconductor chip.

7. The method of claim 1, wherein the removing the first carrier substrate comprises exposing lower surfaces of the plurality of sacrificial pads and a lower surface of the molding layer.

8. The method of claim 1, wherein the forming the plurality of sacrificial pads comprises forming the plurality of sacrificial pads via patterning by a photolithography process and an etching process.

9. A method of manufacturing a semiconductor package, the method comprising:
forming a plurality of sacrificial pads on a first carrier substrate;
forming a plurality of sacrificial solder bumps on the plurality of sacrificial pads;
arranging, on the plurality of sacrificial solder bumps, a first semiconductor chip, a second semiconductor chip, a first passive device, and a second passive device, wherein each the first semiconductor chip, the second semiconductor chip, the first passive device, and the second passive device comprises a lower surface on which a plurality of metal pillars are provided;
bonding the plurality of sacrificial solder bumps to the plurality of metal pillars, such that the plurality of sacrificial sold bumps is between the first carrier substrate and each of the first semiconductor chip, the second semiconductor chip, the first passive device, and the second passive device;
forming a molding layer that surrounds the plurality of sacrificial pads, the plurality of sacrificial solder bumps, the plurality of metal pillars, the first semiconductor chip, the second semiconductor chip, the first passive device, and the second passive device;
attaching a second carrier substrate onto the first semiconductor chip and the second semiconductor chip, and removing the first carrier substrate;
exposing surfaces of the plurality of metal pillars by grinding and removing all of the plurality of sacrificial pads and the plurality of sacrificial solder bumps;
forming a redistribution layer on the plurality of metal pillars and the molding layer;
forming an external connection terminal on the redistribution layer; and
removing the second carrier substrate.

10. The method of claim 9, wherein the bonding the plurality of sacrificial solder bumps to the plurality of metal pillars comprises self-aligning the plurality of metal pillars and the plurality of sacrificial pads with each other, due to surface tension of the plurality of sacrificial solder bumps, by performing a reflow process on the plurality of sacrificial solder bumps.

11. The method of claim 9, wherein the plurality of metal pillars and the plurality of sacrificial pads each comprise copper (Cu),
the plurality of metal pillars and the redistribution layer are in direct contact with each other and are electrically connected with each other, and
an interface between the molding layer and the redistribution layer and an interface between the plurality of metal pillars and the redistribution layer are coplanar with each other.

12. The method of claim 11, wherein a pitch of the plurality of metal pillars is about 20 micrometers to about 100 micrometers, and
a separation distance between the first semiconductor chip and the first passive device and a separation distance between the second semiconductor chip and the second passive device are each about 10 micrometers to about 1,000 micrometers.

13. The method of claim 9, wherein the redistribution layer comprises a vertical via that has a width in a horizontal direction that gradually decreases toward the lower surface of the first semiconductor chip or the lower surface of the second semiconductor chip.

14. The method of claim 9, wherein the removing the first carrier substrate comprises exposing lower surfaces of the plurality of sacrificial pads and a lower surface of the molding layer.

15. The method of claim 9, wherein the forming the plurality of sacrificial pads comprises forming the plurality of sacrificial pads via patterning by a photolithography process and an etching process.

16. A method of manufacturing a semiconductor package, the method comprising:
forming a plurality of sacrificial pads on a first carrier substrate;
forming a plurality of sacrificial solder bumps on the plurality of sacrificial pads;
arranging, on the plurality of sacrificial solder bumps, a first semiconductor chip, a second semiconductor chip, and a bridge die, each of the first semiconductor chip, the second semiconductor chip, and the bridge die comprising a lower surface on which a plurality of metal pillars and a protective insulating layer surrounding side surfaces of the plurality of metal pillars are provided;
bonding the plurality of sacrificial solder bumps to the plurality of metal pillars, such that the plurality of sacrificial solder bumps is between the first carrier substrate and each of the first semiconductor chip, the second semiconductor chip, and the bridge die;
forming a molding layer that surrounds the plurality of sacrificial pads, the plurality of sacrificial solder bumps, the protective insulating layer, the first semiconductor chip, the second semiconductor chip, and the bridge die;
attaching a second carrier substrate onto the first semiconductor chip and the second semiconductor chip, and removing the first carrier substrate;
exposing surfaces of the plurality of metal pillars and a surface of the protective insulating layer by grinding and removing all of the plurality of sacrificial pads and the plurality of sacrificial solder bumps;
forming a first redistribution layer on the plurality of metal pillars and the protective insulating layer;
attaching a third carrier substrate onto the first redistribution layer and removing the second carrier substrate;
forming a plurality of connection posts that are arranged around the first semiconductor chip and the second semiconductor chip, and are electrically connected with the first redistribution layer through the molding layer;
forming a second redistribution layer on the molding layer, the plurality of connection posts, the first semiconductor chip, and the second semiconductor chip;
arranging a third semiconductor chip on the second redistribution layer; and
removing the third carrier substrate.

17. The method of claim 16, wherein the third semiconductor chip comprises a single logic chip, and
the first semiconductor chip and the second semiconductor chip are a set of memory chips that are configured to merge data with each other.

18. The method of claim 17, wherein the bridge die is configured to transmit data signals between the first semiconductor chip and the second semiconductor chip, and
the third semiconductor chip is electrically connected with the first redistribution layer via the second redistribution layer and the plurality of connection posts.

19. The method of claim 16, wherein the bonding the plurality of sacrificial solder bumps to the plurality of metal pillars comprises self-aligning the plurality of metal pillars and the plurality of sacrificial pads with each other, due to surface tension of the plurality of sacrificial solder bumps, by performing a reflow process on the plurality of sacrificial solder bumps.

20. The method of claim 16, wherein the first redistribution layer comprises a first vertical via that has a width in a horizontal direction that gradually decreases toward the lower surface of the first semiconductor chip or the lower surface of the second semiconductor chip, and
the second redistribution layer comprises a second vertical via that has a width in the horizontal direction that gradually decreases toward an upper surface of the first semiconductor chip or an upper surface of the second semiconductor chip.
